(19) United States
(12) Patent Application Publication
(10) Pub. No.: US 2008/0042181 A1
(43) Pub. Date: Feb. 21, 2008

(54) SEMICONDUCTOR DEVICE

(75) Inventors: Masatoshi Watarai, Kanagawa (JP); Shintarou Arai, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/840,246

(22) Filed: Aug. 17, 2007

(30) Foreign Application Priority Data
Aug. 21, 2006 (JP) 2006-224182

(51) Int. Cl. H01L 27/108

(52) U.S. Cl. 257/306; 257/E27.084

(57) ABSTRACT

A semiconductor device in which capacitance per unit area can be enlarged without imposing any limitations upon layout has both a DRAM region and a logic region. The DRAM region and the logic region each have a plurality of cells provided with a respective capacitance element. Each capacitance element has an upper electrode, a lower electrode and a dielectric film sandwiched between the upper and lower electrodes. At least one of the upper electrode and lower electrode in the DRAM region is electrically isolated for every cell. In the logic region, the upper electrode, lower electrode and dielectric film are extended so as to be continuous from cell to cell of the plurality of cells.

### RELATED APPLICATION

This application is based upon and claims the benefit of the priority of Japanese patent application No. 2006-224182, filed on Aug. 21, 2006, the disclosure of which is incorporated herein in its entirety by reference thereto.

### FIELD OF THE INVENTION

This invention relates to a semiconductor device having capacitance elements. More particularly, the invention relates so a semiconductor device bearing a mixture of a dynamic random-access memory (DRAM) region and logic region.

### BACKGROUND OF THE INVENTION

In an eDRAM (embedded DRAM) in which a DRAM region and a logic region are mixed on a single semiconductor chip, it is known to form a capacitance element, which has a structure identical with that of a capacitance element in the DRAM region, as a capacitance element in the logic region (e.g., see the specification of Patent Document 1). FIGS. 6A and 6B are sectional views illustrating a DRAM region 21a and a logic region 21b in an eDRAM according to the prior art. The DRAM region 21a and logic region 21b have a plurality of cells in which are formed identically structured cylinder-type capacitance elements 24a, 24b in which dielectric films 26a, 26b are sandwiched between upper electrodes 25a, 25b and lower electrodes 27a, 27b, respectively. The lower electrodes 27a and 27b in the DRAM region 21a and logic region 21b, respectively, are formed separately for every cell. Transistors having diffusion regions 30a, 30b and gates 29a, 29b are formed on semiconductor substrates 31a, 31b, respectively, on a cell-by-cell basis, and the lower electrodes 27a, 27b are electrically connected with diffusion regions 30a, 30b, respectively, through contacts 28a, 28b, respectively.

### [Patent Document 1]

Japanese Patent Kokai Publication No. JP-P2003-168780

### SUMMARY OF THE DISCLOSURE

The entire disclosure of Patent Document 1 above mentioned is incorporated herein by reference thereto. In the following the present invention provides with analyses.

Owing to the progress that has been made in raising the speed and lowering the power-supply voltage of semiconductor devices in recent years, there is increasing demand for large capacitance elements as a measure for dealing with power-supply noise and soft error. However, in the cylinder-type capacitance element 24b in the logic region 21b of the eDRAM illustrated in FIG. 6B, only the side walls and bottom of each cell can be utilized in accumulating charge and the capacitance per unit area is small. In order to enlarge capacitance in the logic region, it is necessary to increase the number of capacitance elements or to enlarge cell depth. However, this approach enlarges the area and volume of the semiconductor chip. Further, since a transistor must be formed on a per-cell basis, a limitation is imposed upon the layout on the semiconductor substrate. Furthermore, since the contacts connecting the wiring of the logic circuit and the semiconductor substrate cannot be placed at locations where the capacitance elements have been placed, a limitation is also imposed upon the wiring of the logic circuit.

Accordingly, it is an object of the present invention to provide a semiconductor device in which capacitance per unit area can be enlarged without imposing any limitations upon layout.

According to a first aspect of the present invention, there is provided a semiconductor device bearing a mixture of a dynamic random-access memory (DRAM) region and a logic region; the DRAM region and the logic region each having a plurality of cells provided with a capacitance element; the capacitance element having an upper electrode, a lower electrode and a dielectric film sandwiched between the upper and lower electrodes; and the upper electrode, lower electrode and dielectric film in the logic region each being extended so as to be continuous from cell to cell of the plurality of cells.

In a preferred mode according to the first aspect of the invention, the semiconductor device may have transistors electrically connected to the capacitance elements, and the number of transistors in the logic region is smaller than the number of the plurality of cells.

In a preferred mode according to the first aspect of the invention, the capacitance element in the logic region has a contact hole that passes through the capacitance element, and an edge portion of the lower electrode is not exposed to an inner surface of the contact hole. In accordance with a preferred mode, an opening in the lower electrode in the contact hole is larger than an opening in the upper electrode, and an inner surface of the opening in the lower electrode is covered by the dielectric film and the upper electrode.

In a preferred mode according to the first aspect of the invention, the capacitance element is a cylinder-type or parallel-plate-type capacitance element.

The meritorious effects of the present invention are summarized as follows.

In accordance with the first aspect of the present invention, the upper electrodes, lower electrodes and dielectric films of the capacitor element in the logic region are made continuous from cell to cell, thereby enabling a portion in the DRAM region that is not usually utilized to accumulate charge to be utilized for accumulating charge. As a result, capacitance per unit area can be increased. Further, since contacts for electrically connecting logic circuits and the semiconductor substrate can be formed at any locations, capacitance can be increased independently of the logic circuits and layout on the semiconductor substrate.

In accordance with a preferred mode of the first aspect of the invention, the upper electrode and lower electrode in the logic region are each formed continuous by extending over a plurality of cells. This means that a transistor electrically connected to the upper electrode or lower electrode need not be formed for every cell. In addition, there is a greater degree of freedom in terms of locations where the transistors can be placed. As a result, the area required for the transistors can be reduced and it is possible to raise the degree of freedom in terms of layout on the semiconductor substrate.

In accordance with a preferred mode of the first aspect of the invention, the lower electrode is not exposed to the inner surface of a contact hole formed in the capacitance element, thereby making it possible to prevent a short-circuit between the upper and lower electrodes.

In accordance with a preferred mode of the first aspect of the invention, various capacitance elements can be formed. This affords a higher degree of freedom in terms of designing semiconductor devices.

Other features and advantages of the present invention will be apparent from the following description taken in conjunction with the accompanying drawings, in which like reference characters designate the same or similar parts throughout the figures thereof.

### BRIEF DESCRIPTIONS OF THE DRAWINGS

FIGS. 1A and 1B are schematic sectional views illustrating a semiconductor device according to a first exemplary embodiment of the present invention;

FIG. 2 is a schematic plan view illustrating the surface of an upper electrode in a logic region of a semiconductor device according to a second exemplary embodiment of the present invention;

FIG. 3 is a schematic sectional view taken along line III-III of FIG. 2;

FIGS. 4A and 4B are enlarged sectional views of a contact hole in a capacitance element;

FIG. 5 is a schematic partial sectional view of a logic region in a semiconductor device according to a third exemplary embodiment of the present invention; and

FIGS. 6A and 6B are schematic sectional views illustrating a semiconductor device according to the conventional art.

### PREFERRED MODES OF THE INVENTION

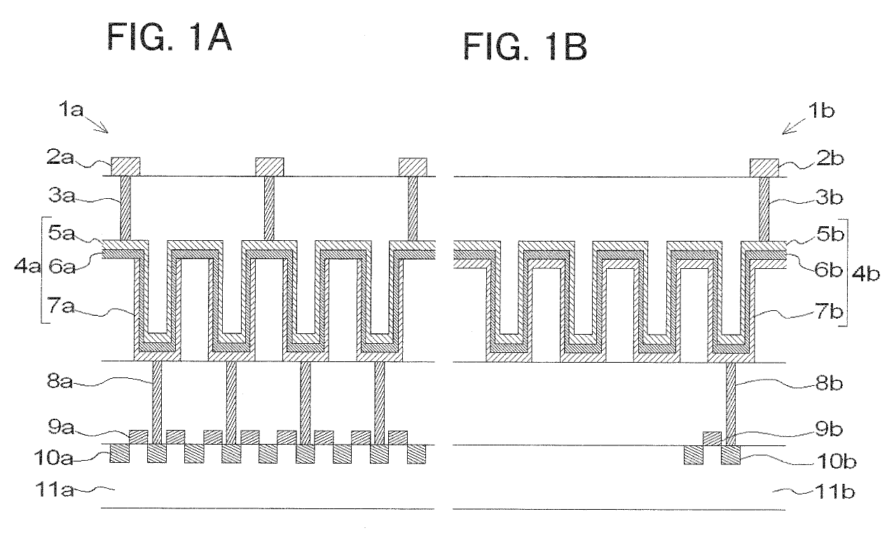

A first exemplary embodiment of the present invention will now be described. FIGS. 1A and 1B are schematic sectional views illustrating a semiconductor device according to a first exemplary embodiment of the present invention. The semiconductor device according to the first exemplary embodiment of the invention is one bearing a mixture of a DRAM region 1a, which is indicated in FIG. 1A, and a logic region 1b indicated in FIG. 1B. The DRAM region 1a and logic region 1b have a plurality of cells provided with cylinder-type capacitance elements 4a, 4b formed by upper electrodes (e.g., cell plate electrodes) 5a, 5b, dielectric films 6a, 6b and lower electrodes (e.g., storage plates) 7a, 7b, respectively. In the DRAM region 1a, the upper electrode 5a and dielectric film 6a are formed so as to be continuous (in meandering fashion in terms of the drawings) from cell to cell. The lower electrode 7a, however, is separate for each cell. In the logic region 1b, on the other hand, the lower electrode 7b also is formed so as to be continuous (in meandering fashion in terms of the drawings) from cell to cell (i.e., the lower electrode 7b is not separate for each cell). For example, as illustrated in FIG. 1B, the lower electrode 7b is extended along the dielectric film 6b and upper electrode 5b so as to interconnect the cells at the upper portions thereof. As a result, even the dielectric film 6b at the upper portions of cells not exploited in the DRAM region 1a can be utilized for accumulating charge, and the capacitance per unit area is increased. Accordingly, the capacitance elements in the logic region of the semiconductor device according to the invention can be used as decoupling elements, by way of example.

Further, in the DRAM region 1a, transistors are formed on a semiconductor substrate 11a cell by cell, and the lower electrode 7a of the capacitance element and one diffusion region 10a (source region or drain region) of each cell are electrically connected through a respective contact 8a. In the logic region 1b, on the other hand, transistors are not formed on a semiconductor substrate 11b cell by cell. The continuous lower electrode 7b is electrically connected at a desired portion thereto to one diffusion region 10b (source region or drain region) through a contact 8b. That is, the number of transistors electrically connected to cells having the capacitance element 4b is smaller than the number of cells in the logic region. As a result, the capacitance element 4b can be formed even at a location where a transistor electrically connected to the capacitance element 4b and the contact 8b cannot be formed. This makes it possible to raise the degree of freedom of design. It should be noted that the electrical connection between the other diffusion region 10a and upper electrode 5b is not shown in FIGS. 1A and 1B.

In the logic region 1b shown in FIG. 1B, the lower electrode 7b is extended so as to interconnect all of the cells (four in FIG. 1B). However, the lower electrode 7b need not be continuous between all of the cells that have been formed in the logic region lb. In the present invention, it will suffice if at least some (for instance, two) lower electrodes 7b are extended so as to be continuous from cell to cell of a plurality of the cells. That is, the semiconductor device of the present invention may just as well have lower electrodes 7b that are electrically isolated between cells.

As shown in FIGS. 1A and 1B, the capacitance element 4a of the DRAM region 1a and the capacitance element 4b of the logic region 1b have been formed in the same layer and are identical in structure (diameter, depth and shape). However, the capacitance element 4a of the DRAM region 1a and the capacitance element 4b of the logic region 1b need not be identical in structure, and the diameter, depth and shape, etc., of the capacitance elements 4a, 4b can be modified as appropriate. Further, the capacitance elements 4a, 4b are not limited to the cylinder type depicted in FIGS. 1A and 1B, and various types can be applied. For example, parallel-plate-type capacitance elements of the kind described later in a third exemplary embodiment can be applied.

As for the upper electrodes 5a, 5b and lower electrodes 7a, 7b, it is possible to use a conductor (e.g., Pt, Ru, RuO₂, SrRuO₃, Ir, IrO₂, etc.) containing a metal such as Pt, Ru, Sr or Ir, or a conductor comprising an electrically conductive metal nitride such as tungsten nitride (WN) or titanium nitride (TiN). As for the dielectric films 6a, 6b, it is possible to use a dielectric (e.g., SiO₂, Si₃N₄, Ta₂O₅, BaTiO₃, SrTiO₃, Y₂O₃, HfO₂, ZrO₂, Nb₂O₅, etc.) containing an oxide or a nitride of such as Si, Ta, Hf, Zr, Ti, Ba, Sr or Y, or a mixture thereof.

The capacitance element 4b of the logic region 1b can be formed at the same time as the capacitance element 4a of the DRAM region 1a.

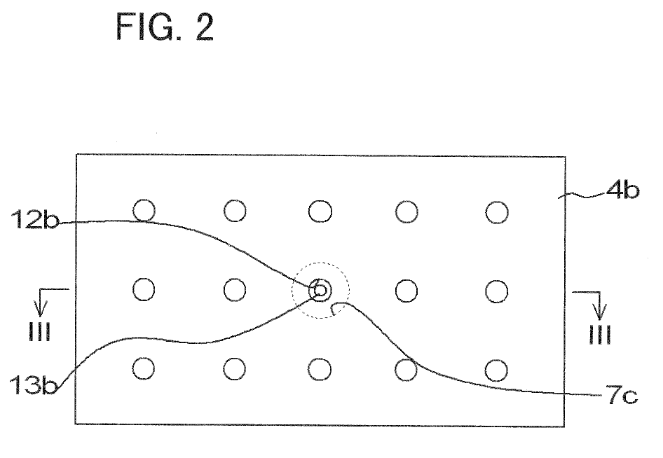

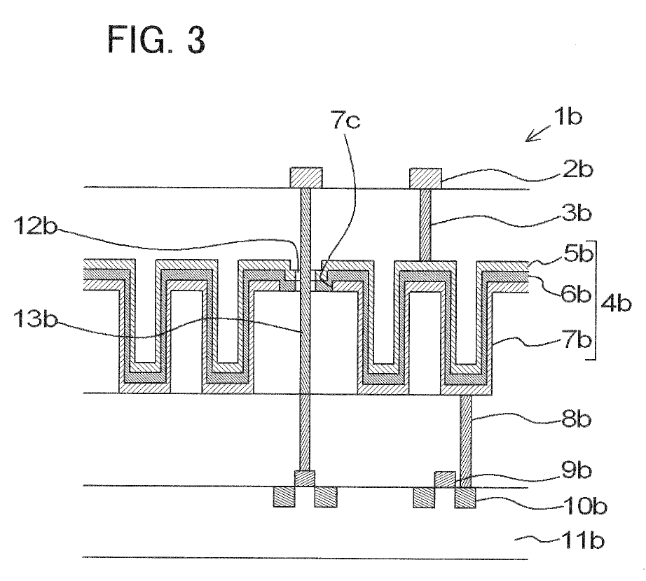

A semiconductor device according to a second exemplary embodiment of the present invention will now be described. FIG. 2 is a schematic plan view illustrating the surface of an upper electrode in the logic region of a semiconductor device according to the second exemplary embodiment of the present invention, and FIG. 3 is a schematic sectional view taken along line III-III of FIG. 2. Described in the second exemplary embodiment will be the form of a contact 13b (extending throughout a via hole) for electrically connecting the semiconductor substrate 11b and a wiring layer 2b. The basic form of the semiconductor device illustrated in FIGS. 2 and 3 is similar to that of the first exemplary embodiment. The logic region 1b has a plurality of cells each having the cylinder-type capacitance element 4b, and the lower electrode 7b is formed along the upper electrode 5b and upper electrode 5b so as to be continuous from cell to cell.

This exemplary embodiment differs from the first exemplary embodiment in that the capacitance element 4b is formed to have a penetrating contact (via) hole 12b through which the contact (or interconnect) 13b is passed. The contact 13b electrically contacts the wiring layer 2b and the contact 8b connected to the semiconductor substrate 11b (e.g., to a gate electrode 9b or to the diffusion region 10b). Since the lower electrode 7b is formed so as to be continuous from cell to cell, the contact hole 12b can be formed at a desired position in accordance with the wiring layer 2b or layout on the semiconductor substrate 11b.

The contact hole 12b preferably is formed in such a manner that the lower electrode 7b will not be exposed to the edge face (inner surface) of the contact hole 12b. For example, as illustrated in FIGS. 2 and 3, it is preferred that the contact hole 12b be formed in such a manner that the size of the opening in the lower electrode 7b is made larger than the size of the opening in the dielectric film 6b and that an edge portion 7c (namely the inner surface of the opening) of the lower electrode 7b facing the contact hole 12b is covered by the dielectric film 6b and upper electrode 5b. Alternatively, the contact hole 12b may be formed in such a manner that inner surface of the contact hole 12b is covered by the upper electrode 5b (although it is so arranged that the upper electrode 5b and lower electrode 7b are not short-circuited).

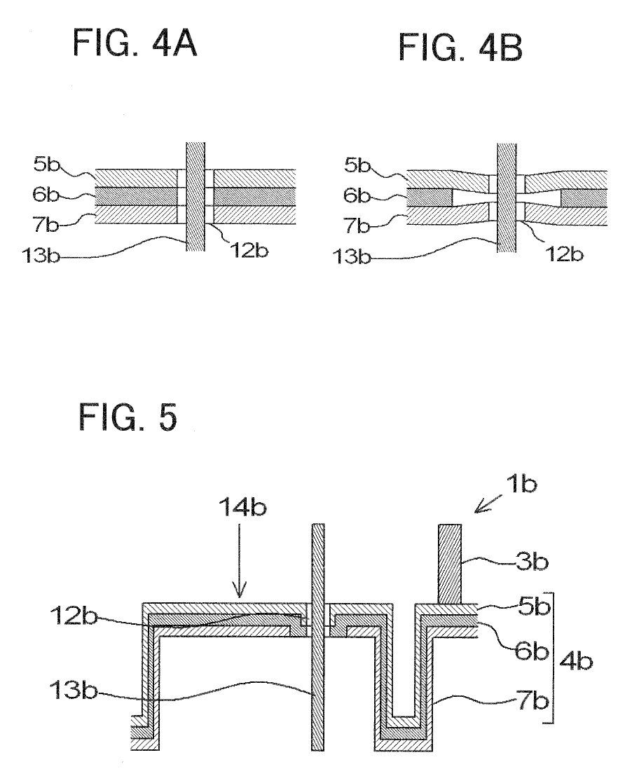

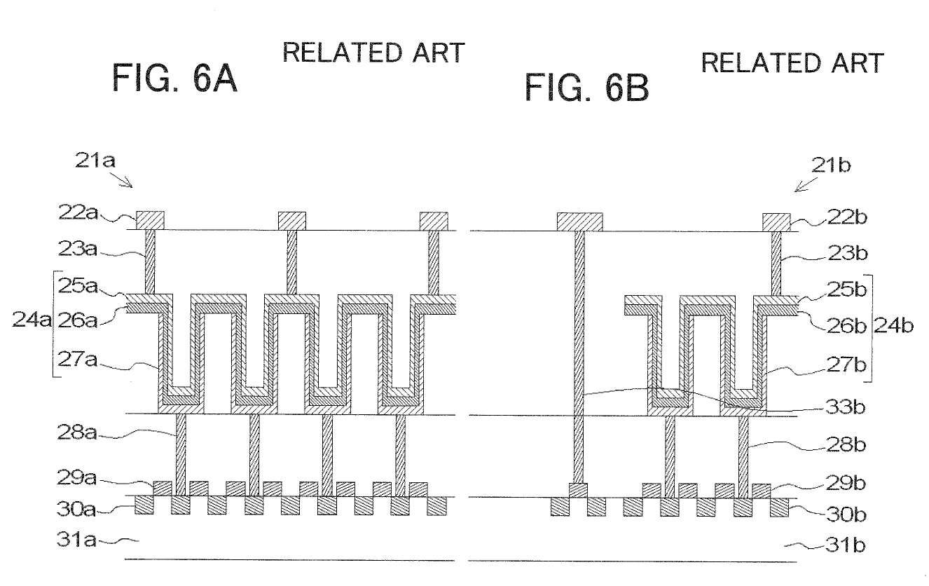

The advantage of the contact hole 12b shown in FIGS. 2 and 3 will be described. FIGS. 4A and 4B are enlarged cross sectional views of the inner surface of the contact hole 12b. In this case, the contact hole 12b exposes the edge portion of the lower electrode 7b. If the dielectric film 6b is withdrawn by etching from the state shown in FIG. 4A to the state shown in FIG. 4B, there is the danger that the upper electrode 5b and lower electrode 7b will be short-circuited. However, in accordance with the second exemplary embodiment, if the contact hole 12b is formed in such a manner that the lower electrode 7b is not exposed to the inner surface of the contact hole 12b, as illustrated in FIG. 3, then short-circuiting of the upper electrode 5b and lower electrode 7b can be prevented even if the edge portion of the dielectric film 6b is etched away.

Next, a semiconductor device according to a third exemplary embodiment of the present invention will be described. FIG. 5 is a schematic partial sectional view of a logic region in a semiconductor device according to a third exemplary embodiment of the present invention. The third exemplary embodiment is similar to the first and second exemplary embodiments in that the lower electrode has not been separated for every cell. In the third exemplary embodiment, however, a parallel-plate-type capacitance element 14b has been formed in addition to the cylinder-type capacitance element 4b. In accordance with the third exemplary embodiment, therefore, if the parallel-plate capacitance element is formed, then capacitance can be increased even in a region in which a capacitance element cannot be provided in cylindrical form. In addition, the lower electrode can be extended as a continuum so as not to be a separate lower electrode at each cell.

It should be noted that inter-layer insulating films, gate insulating films, side walls, silicide layers and STI (Shallow Trench Isolation) regions, etc., are not illustrated in FIGS. 1A to 5. However, it goes without saying that the semiconductor device according to the present invention is capable of being provided with these elements (not shown) in a desired form.

As many apparently widely different exemplary embodiments of the present invention can be made without departing from the spirit and scope thereof, it is to be understood that the invention is not limited to the specific exemplary embodiments thereof except as defined in the appended claims.

What is claimed is:

1. A semiconductor device comprising:
a mixture of a dynamic random-access memory (termed DRAM hereinafter) region and a logic region;
wherein the DRAM region and the logic region each have a plurality of cells provided with a capacitance element;
said capacitance element has an upper electrode, a lower electrode and a dielectric film sandwiched between the upper and lower electrodes; and
the upper electrode, lower electrode and dielectric film in said logic region are extended so as to be continuous from cell to cell of the plurality of cells.

2. The device according to claim 1, further comprising transistors electrically connected to said capacitance elements;
wherein the number of transistors in said logic region is smaller than the number of the plurality of cells.

3. The device according to claim 1, wherein the capacitance element in said logic region has a contact hole that passes through the capacitance element; and
an edge portion of the lower electrode is not exposed to an inner surface of the contact hole.

4. The device according to claim 2, wherein the capacitance element in said logic region has a contact hole that passes through the capacitance element; and
an edge portion of the lower electrode is not exposed to an inner surface of the contact hole.

5. The device according to claim 3, wherein an opening in the lower electrode in the contact hole is larger than an opening in the upper electrode; and
an inner surface of the opening in the lower electrode is covered by the dielectric film and the upper electrode.

6. The device according to claim 4, wherein an opening in the lower electrode in the contact hole is larger than an opening in the upper electrode; and
an inner surface of the opening in the lower electrode is covered by the dielectric film and the upper electrode.

7. The device according to claim 1, wherein the capacitance element is a cylinder-type or parallel-plate-type capacitance element.

8. The device according to claim 1, wherein the capacitance element comprises a cylinder-type capacitance element.

9. The device according to claim 1, wherein the capacitance element comprises a parallel-plate-type capacitance element.
